(19) United States
(12) Patent Application Publication
(10) Pub. No.: US 2018/0254385 A1
(43) Pub. Date: Sep. 6, 2018

(54) OPTOELECTRONIC COMPONENT AND METHOD OF PRODUCING AN OPTOELECTRONIC COMPONENT

(71) Applicant: OSRAM Opto Semiconductors GmbH, Regensburg (DE)

(72) Inventors: Thomas Kippes, Neumarkt (DE); Claus Jaeger, Regensburg (DE)

(21) Appl. No.: 15/756,651

(22) PCT Filed: Aug. 30, 2016
(86) PCT No.: PCT/EP2016/070361

§ 371 Date: Mar. 1, 2018

(30) Foreign Application Priority Data
Sep. 2, 2015 (DE) 10 2015 114 661.4

(51) Int. Cl. H01L 33/46; H01L 33/48; H01L 23/00

(52) U.S. Cl. CPC H01L 33/46; H01L 33/48; H01L 2224/8592; H01L 2224/48091; H01L 24/47

(57) ABSTRACT

An optoelectronic component includes a semiconductor chip, the semiconductor chip emitting infrared radiation; a reflector that reflects the infrared radiation of the semiconductor chip; and a filter configured in the form of a coating, the filter being transparent for the infrared radiation of the semiconductor chip, wherein visible light striking the optoelectronic component being absorbed to at least 75%.

### TECHNICAL FIELD

This disclosure relates to an optoelectronic component and a method of producing an optoelectronic component.

### BACKGROUND

Components that emit infrared radiation such as are, for example, built into smart phones or tablet PCs are visible through the reflector built into the component when the component is applied below a glass plate, for example, the cover plate of the device.

There is nonetheless a need to provide an improved optoelectronic component and an improved production method for such a component.

### SUMMARY

We provide an optoelectronic component including a semiconductor chip, the semiconductor chip emitting infrared radiation; a reflector that reflects the infrared radiation of the semiconductor chip; and a filter configured in the form of a coating, the filter being transparent for the infrared radiation of the semiconductor chip, wherein visible light striking the optoelectronic component being absorbed to at least 75%.

We also provide a method of producing an optoelectronic component including placing an optoelectronic semiconductor chip on a carrier, electrically contacting the semiconductor chip, placing a reflector on the carrier, and applying a filter by applying a coating.

### BRIEF DESCRIPTION OF THE DRAWINGS

FIG. 1 schematically shows a cross section through one optoelectronic component.

FIG. 2 schematically shows a cross section through another optoelectronic component.

FIG. 3 schematically shows a plan view of an optoelectronic component.

FIG. 4 schematically shows another cross section through an optoelectronic component.

### LIST OF REFERENCES

100 optoelectronic component
101 recess
102 material
110 semiconductor chip
120 reflector
121 metal layer
130 filter
131 coating
140 bonding wire
141 first conductive region
142 second conductive region

### DETAILED DESCRIPTION

Our optoelectronic component comprises a semiconductor chip, the semiconductor chip emitting infrared radiation. The optoelectronic component furthermore comprises a reflector that reflects the infrared radiation of the semiconductor chip. A filter is furthermore provided, which is configured in the form of a coating. The filter is transparent for the infrared radiation of the semiconductor chip. Visible light striking the optoelectronic component is absorbed to at least 75%. Preferably, visible light is absorbed to 85%, particularly preferably to 95%, by the component when the light strikes the component. The filter, which is configured in the form of a coating, makes it possible to have an optoelectronic infrared component that is straightforward to produce and satisfies the requirements that the component, for example, in a smartphone or in a tablet PC, is as far as possible invisible. When more visible light striking the component is absorbed, the object is achieved commensurately better.

The thickness of the coating forming the filter is at most 50 μm. Such thin coatings can be produced simply, for example, by a spray coating process.

At least 90% of the infrared radiation emitted by the semiconductor chip may pass through the filter. The effect achievable by the high transmission of the infrared radiation through the filter is that the majority of the infrared light leaves the component and is therefore available outside the component.

The filter may comprise a matrix material with a colorant. It is also possible to mix a plurality of colorants and introduce them into a matrix material.

The matrix material may comprise an epoxy resin, silicone, plastic or lacquer. It is straightforward to introduce colorants that carry out the absorption of visible light, into these materials.

The reflector may be coated with silver or aluminum. Silver or aluminum are good reflector materials that reflect infrared radiation well. On the other hand, however, silver and aluminum also reflect visible light well. By reflection of visible light on a silver or aluminum layer, the reflector of the component is visible. To avoid this, the additional filter coating is provided. Silver and aluminum in this case reflect the spectral range of the visible light. The filter should therefore absorb the spectral range of the visible light.

The reflector may be coated with gold. Gold is suitable to coat the reflector since it has good reflection properties in the infrared spectral range. Infrared radiation with a wavelength of less than 1 μm is reflected better by gold than by silver or aluminum.

The reflector may be coated with gold, and the filter absorbs only the spectral ranges that are reflected by the gold. Green and blue light is absorbed strongly by the gold layer itself. Provision does not therefore need to be made for the filter to absorb the green or blue light fully. The spectral range of the visible light absorbed by the filter may be selected such that only red and yellow light is absorbed almost fully by the filter. In this case, a combined system consisting of the filter and the gold coating of the reflector is configured such that visible light striking the optoelectronic component is absorbed to at least 75%, preferably to 85% and particularly preferably to 95%.

The semiconductor chip may be covered with the filter. This is the case in particular when the semiconductor chip is initially fitted into the component with the reflector, and the coating consisting of the matrix element and the colorant is subsequently applied onto the component. By application of the filter on the semiconductor chip, in addition to reflection of the visible light on the reflector, the visible light can also be absorbed for the most part on the semiconductor chip by the filter.

The semiconductor chip may be covered not with the filter but only with the reflector. In this case, it is advantageous to select the absorption of the combined system of the reflector and the filter such that visible light is absorbed to 75%, preferably to 85%, and particularly preferably to 95%. If the reflector has a gold coating, it is readily possible to provide only a narrower spectral range of the visible light, in particular for red and yellow light, for the filter. In this way, a very economical component can be produced.

A method of producing an optoelectronic component comprises:
placing an optoelectronic semiconductor chip on a carrier,
electrically contacting the semiconductor chip,
placing a reflector on the carrier, and
applying a filter by applying a coating.

The advantageous optoelectronic component can be produced by this method.

The filter may be applied after the placement and contacting of the semiconductor chip. In this case, the filter covers the semiconductor chip. Visible light striking the semiconductor chip is likewise absorbed so that no reflection of the visible light takes place on the semiconductor chip. The contours of the semiconductor chip are therefore not visible.

The filter may be applied before the placement and contacting of the semiconductor chip. The filter therefore does not cover the semiconductor chip, but the reflector and the carrier with the applied filter can be prefabricated. Cost savings can be achieved in this way.

The matrix material with the colorant may be configured to passivate the metal surface of the reflector, in particular the aluminum or silver surface of the reflector. This means that the metal surface of the reflector is fully covered by the matrix material so that corrosion of the aluminum or silver surface is made more difficult. The matrix material with the colorant may therefore be used as corrosion protection of the metal reflector layer.

The wavelength of the light-emitting, or infrared radiation-emitting, semiconductor chip may be 810 nm. The filter may absorb the visible light in a spectral range of 400 to 780 nm to 75%, preferably to 85% and particularly preferably to 95%.

The wavelength of the semiconductor chip may be much more than 800 nm, for example, 950 nm. In this case, the filter may be configured to absorb visible light in a spectral range of 400 to 800 nm to 75%, preferably to 85% and particularly preferably to 95%.

The above-described properties, features and advantages, as well as the way in which they are achieved, will become more clearly and readily comprehensible in conjunction with the following description of the examples, which will be explained in more detail in connection with the drawings.

FIG. 1 shows a cross section through an optoelectronic component 100. There is a recess 101 in a material 102, the material 102 forming the housing of the optoelectronic component 100. The recess 101 is covered with a metal layer 121 so that a reflector 120 is formed. The reflector 120 is covered with a filter 130. A semiconductor chip that emits infrared radiation is arranged on the filter 130. The filter 130 is configured to absorb visible light striking the optoelectronic component 100 to at least 75%. The filter 130 prevents reflections of the reflector 120 in the visible wavelength range from being seen outside the optoelectronic component 100.

Provision may be made that the filter 130 does not cover the reflector 120 in a subregion, and that the semiconductor chip 110 is arranged inside this subregion, i.e., directly on the reflector 120. This allows electrical contacting of the lower side, i.e., the side of the semiconductor chip facing away from the reflector 120.

It is likewise possible that the reflector 120 also has an opening in a subregion, and the semiconductor chip 110 is arranged in the opening of the reflector 120 and of the filter 130.

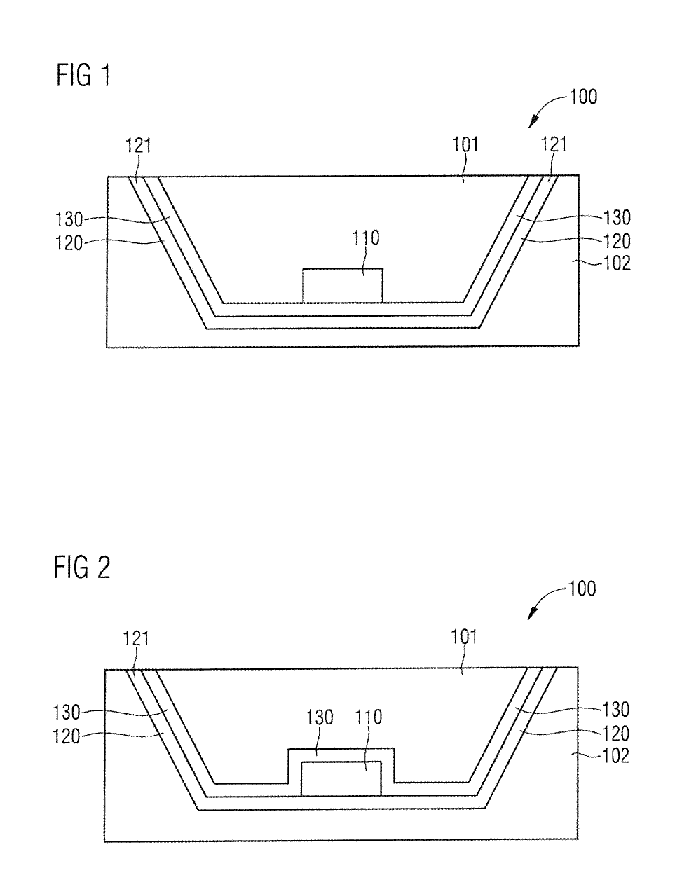

FIG. 2 shows a cross section through another examples of an optoelectronic component 100. A recess 101 in a material 102 again forms the basic shape of the housing of the optoelectronic component 100. The recess 101 is covered with a metal layer 121 that again forms the reflector 120. A semiconductor chip 110 that emits infrared radiation is applied on the material 102. A filter 130 is applied on the reflector 120 and on the semiconductor chip 110. The filter 130 thus also covers the semiconductor chip 110. In this example, in addition to suppression of the reflection of visible light on the reflector 120, the visible light striking the semiconductor chip 110 is also absorbed.

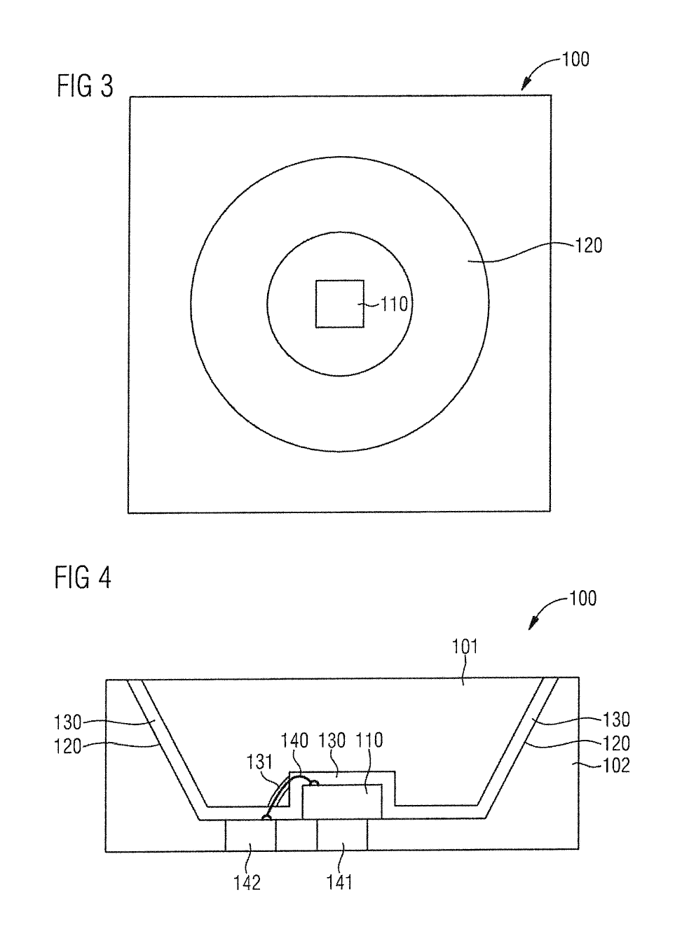

FIG. 3 shows a plan view of an optoelectronic component 100, a semiconductor chip 110 being applied in the middle of a circular reflector 120. FIG. 3 thus corresponds to the optoelectronic component without the filter 130, and the reflector 120 and the semiconductor chip 110 are visible. The effect achievable by applying a filter 130 on the entire optoelectronic component 100 is that visible light is no longer reflected on the semiconductor chip 110 or on the reflector 120 so that the contours of the optoelectronic component 100 are invisible to the human eye since visible light striking the optoelectronic component 100 is not reflected by the optoelectronic component 100.

The thickness of the filter 130 may at most be 50 μm. Using a 50 μm thick filter 130, an optoelectronic component that absorbs visible light can be produced.

At least 90% of the infrared radiation emitted by the semiconductor chip may pass through the filter 130. This is advantageous in the example of FIG. 2, but also useful in the example of FIG. 1, as the infrared radiation emerging from the semiconductor chip 110 and striking the reflector 120 must first pass through the filter layer 130.

The filter may comprise a matrix material with colorant. The matrix material in this case provides the structure of the filter layer, while the colorant performs the absorption of visible light. The matrix material may be an epoxy resin, silicone, plastic or lacquer. The matrix material may be a material that reduces corrosion of the surface of the reflector 120.

The reflector may be coated with silver or aluminum. Silver and aluminum are highly suitable as reflectors for infrared radiation, but also reflect the entire visible wavelength range. The filter 130 is applied on the silver or aluminum coating of the reflector 120.

The reflector 120 may be coated with gold. A gold coating of the reflector 120 is highly suitable to reflect infrared radiation emerging from the light-emitting semiconductor chip 110. However, gold primarily reflects light in the red and yellow wavelength range, while green and blue light are predominantly absorbed by gold. The filter 130 may therefore be configured so that only light in the yellow and red wavelength range is absorbed by the filter 130.

A combined system consisting of the filter 130 and the gold coating of the reflector 120 may be configured to absorb visible light striking the optoelectronic component 100 to at least 75%. This is particularly advantageous in the example of FIG. 1, in which the semiconductor chip 110 is not covered with the filter 130 so that absorption of the visible light in the blue and green wavelength range by the filter 130 is not necessary since this wavelength range is reflected almost not at all by the reflector 120.

The semiconductor chip 110 may be covered with the filter 130, as represented in FIG. 2.

The reflector 120 may be coated with gold, and the filter 130 may be configured to absorb visible light to at least 75%. This is advantageous in particular when the optoelectronic component 100 is configured as shown in FIG. 2.

FIG. 4 shows an optoelectronic component 100 having further features that are advantageous for operation of the component 100. The recess 101, the material 102, the semiconductor chip 110, the reflector 120 and the filter 130, again configured as a coating, are in this case arranged as in FIG. 2. Below the semiconductor chip 110, the housing material 102 has a first electrically conductive region 141 that adjoins the semiconductor chip 110 and ensures the electrical contacting of one electrical terminal of the semiconductor chip 110. In the material 102, there is a second electrically conductive region 142 that does not directly adjoin the semiconductor chip 110, but connects to the upper side of the semiconductor chip 110 by a bonding wire 140. The second electrical terminal of the semiconductor chip 110 can be electrically contacted by the second electrically conductive region 142 and the bonding wire 140. The bonding wire 140 may, like the semiconductor chip 110, have a coating 131. The coating 131 of the bonding wire 140 corresponds to the filter 130 of the rest of the component 110. The semiconductor chip 110 has thus first been fitted into the optoelectronic component 100, and the coating with the filter 130 has been carried out after this.

Our method of producing an optoelectronic component 100 comprises:
placing a semiconductor chip 110,
electrically contacting the semiconductor chip 110 by a bonding wire 140 and two electrically conductive regions 141 and 142,
placing a reflector 120, and
applying a filter in the form of a coating.

The filter 130 may be applied after placement and contacting of the semiconductor chip 110 so that a component as represented in FIG. 4 is obtained.

The filter 130 may be applied onto the reflector 120 before placement and contacting of the semiconductor chip 110. This may, in particular, be used to prefabricate the reflector with the applied coating which contains the filter 130, and only then fit them to the semiconductor chip 110.

Although our components and methods have been illustrated and described in detail with the aid of the preferred examples, this disclosure is not restricted to the examples disclosed, and other variants may be derived therefrom by those skilled in the art, without departing from the protective scope of the appended claims.

This application claims priority of DE 10 2015 114 661.4, the subject matter of which is incorporated herein by reference.

1-13. (canceled)

14. An optoelectronic component comprising:
a semiconductor chip, the semiconductor chip emitting infrared radiation;
a reflector that reflects the infrared radiation of the semiconductor chip; and
a filter configured in the form of a coating, the filter being transparent for the infrared radiation of the semiconductor chip,
wherein visible light striking the optoelectronic component being absorbed to at least 75%.

15. The optoelectronic component as claimed in claim 14, wherein the thickness of the filter is at most 50 μm.

16. The optoelectronic component as claimed in claim 14, wherein at least 90% of the infrared radiation emitted by the semiconductor chip passes through the filter.

17. The optoelectronic component as claimed in claim 14, wherein the filter comprises a matrix material with colorant.

18. The optoelectronic component as claimed in claim 17, wherein the matrix material comprises an epoxy resin, silicone, plastic or lacquer.

19. The optoelectronic component as claimed in claim 14, wherein the reflector is coated with silver or aluminum.

20. The optoelectronic component as claimed in claim 14, wherein the reflector is coated with gold.

21. The optoelectronic component as claimed in claim 20, wherein a combined system consisting of the filter and the gold coating of the reflector absorbs visible light striking the optoelectronic component to at least 75%.

22. The optoelectronic component as claimed in claim 14, wherein the semiconductor chip is covered with the filter.

23. The optoelectronic component as claimed in claim 22, wherein the reflector is coated with gold, and the filter absorbs visible light to at least 75%.

24. A method of producing an optoelectronic component comprising:
placing an optoelectronic semiconductor chip on a carrier,
electrically contacting the semiconductor chip,
placing a reflector on the carrier, and
applying a filter by applying a coating.

25. The method as claimed in claim 24, wherein the filter is applied after placement and contacting of the semiconductor chip.

26. The method as claimed in claim 24, wherein the filter is applied before placement and contacting of the semiconductor chip.
